(19) United States
(12) Patent Application Publication
(10) Pub. No.: US 2019/0288501 A1
(43) Pub. Date: Sep. 19, 2019

(54) SEMICONDUCTOR INTEGRATED CIRCUIT

(71) Applicants: Kabushiki Kaisha Toshiba, Tokyo (JP); Toshiba Electronic Devices & Storage Corporation, Tokyo (JP)

(72) Inventor: Kaoru Yanase, Kawasaki Kanagawa (JP)

(21) Appl. No.: 16/114,820

(22) Filed: Aug. 28, 2018

(30) Foreign Application Priority Data
Mar. 19, 2018 (JP) 2018-050995

(51) Int. Cl. H02H 3/08; H03K 5/24; H02H 1/00; H03K 17/082; G01R 19/165

(52) U.S. Cl. CPC H02H 3/085; H03K 5/24; B60R 16/03; H03K 17/0822; G01R 19/16519; H02H 1/0007

(57) ABSTRACT

According to an embodiment, there is provided a semiconductor integrated circuit comprising: a comparator including a first input terminal, a second input terminal, and a third input terminal, the comparator being configured to compare a reference voltage, which is based on at least one of the first voltage and the second voltage, with the third voltage; and a first controller configured to control the switching element in accordance with a comparison result of the comparator.

### CROSS-REFERENCE TO RELATED APPLICATIONS

This application is based upon and claims the benefit of priority from Japanese Patent Application No. 2018-050995, filed Mar. 19, 2018; the entire contents of which are incorporated herein by reference.

### FIELD

Embodiments of the invention relate to a semiconductor integrated circuit.

### BACKGROUND

There is known an overcurrent protection technique which forcibly turns off a MOS transistor when a current flowing in the MOS transistor exceeds a predetermined value.

### BRIEF DESCRIPTION OF THE DRAWINGS

FIG. 1 is a circuit diagram of an overcurrent protection circuit according to a first embodiment.

FIG. 2 is a circuit diagram of a comparator and a constant voltage source in the overcurrent protection circuit according to the first embodiment.

FIG. 3 is a graph illustrating a variation of a reference voltage relative to a chip temperature in the overcurrent protection circuit according to the first embodiment.

FIG. 4 is a circuit diagram of the comparator in the overcurrent protection circuit according to the first embodiment.

FIG. 5 is a circuit diagram of the comparator in the overcurrent protection circuit according to the first embodiment.

FIG. 6 is a circuit diagram illustrating details of an overcurrent protection circuit according to a second embodiment.

FIG. 7 is a graph illustrating a variation of a reference voltage relative to a chip temperature in the overcurrent protection circuit according to the second embodiment.

FIG. 8 is a circuit diagram illustrating details of an overcurrent protection circuit according to a third embodiment.

FIG. 9 is a circuit diagram of a constant current source in the overcurrent protection circuit according to the third embodiment.

### DETAILED DESCRIPTION

According to an embodiment, there is provided a semiconductor integrated circuit comprising: a comparator including a first input terminal configured to receive a first voltage, a second input terminal configured to receive a second voltage having a negative temperature characteristic, and a third input terminal configured to receive a third voltage corresponding to a current flowing in a switching element, the comparator being configured to compare a reference voltage, which is based on at least one of the first voltage and the second voltage, with the third voltage; and a first controller configured to control the switching element in accordance with a comparison result of the comparator, wherein the second voltage is greater than the first voltage at a first temperature and is less than the first voltage at a second temperature which is higher than the first temperature, the comparator is configured to compare the first voltage and the third voltage at the first temperature, and the comparator is configured to compare the second voltage and the third voltage at the second temperature.

Embodiments will be described hereinafter with reference to the accompanying drawings. In this description, common parts are denoted by like reference numerals throughout the drawings.

### 1. First Embodiment

As an example of a semiconductor integrated circuit according to the present embodiment, an overcurrent protection circuit will be described. The overcurrent protection circuit is mounted on, for example, a vehicle such as an automobile, and prevents an overcurrent from being supplied to a microcomputer which controls a power supply device provided in the vehicle.

1.1 Re: Configuration of Overcurrent Protection Circuit 1.

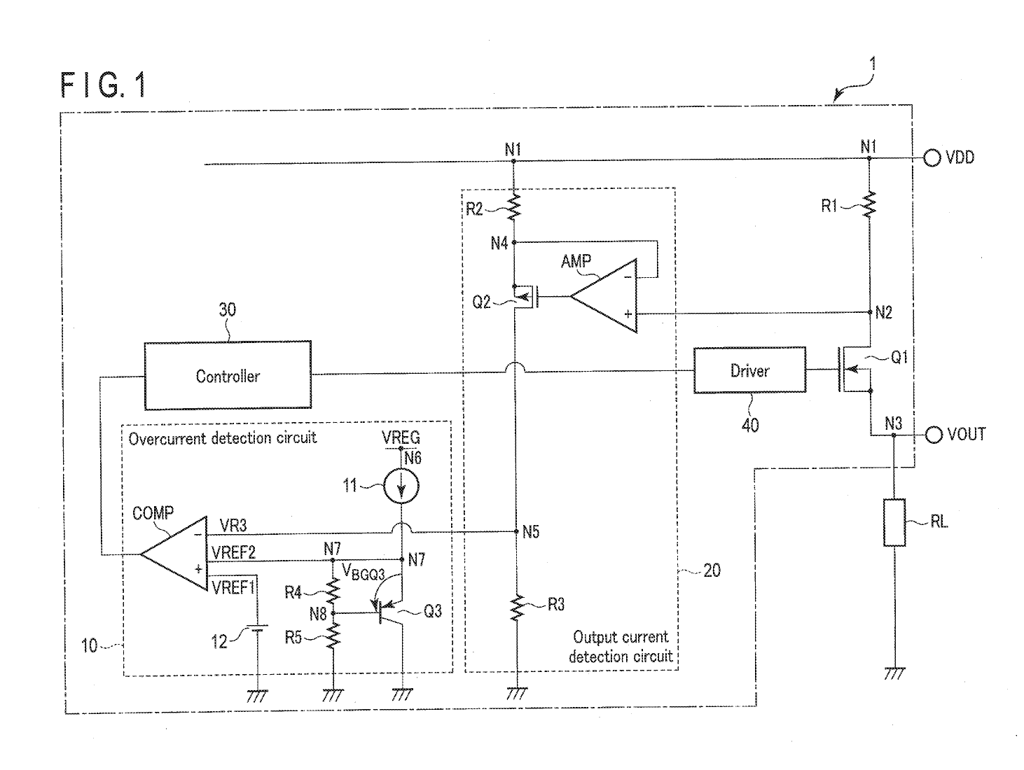

To begin with, the configuration of the overcurrent protection circuit according to the embodiment is described with reference to FIG. 1. As illustrated in FIG. 1, an overcurrent protection circuit 1 includes an overcurrent detection circuit 10, an output current detection circuit 20, a controller 30, a driver 40, an n-channel MOS transistor Q1, and a resistor element R1. In addition, the overcurrent protection circuit 1 operates by being supplied with a power supply voltage VDD, and outputs a voltage VOUT. This output voltage VOUT is delivered to an external load element RL. The load element RL is, for example, the above-described microcomputer or the like.

One end of the resistor element R1 is connected to a node N1, and the other end thereof is connected to a node N2. The power supply voltage VDD is applied to the node N1.

The MOS transistor Q1 has a drain connected to the node N2, has a source connected to a node N3, and has a gate supplied with a voltage corresponding to a predetermined signal level (“L” level or “H” level) from the driver 40. In addition, the voltage at the node N3 is applied to the load element RL as the above-described output voltage VOUT.

The driver 40 controls the MOS transistor Q1 in accordance with an instruction from the controller 30.

The output current detection circuit 20 includes an amplifier AMP, an n-channel MOS transistor Q2, a resistor element R2, and a resistor element R3.

One end of the resistor element R2 is connected to the node N1, and the other end thereof is connected to a node N4.

The amplifier AMP includes a non-inversion input termination (+), an inversion input terminal (−), and an output terminal. The voltage at the node N2 is input to the non-inversion input termination (+) of the amplifier AMP, and the voltage at the node N4 is input to the inversion input terminal (−). In addition, the amplifier AMP supplies a voltage, which corresponds to a difference between the two input voltages, to a gate of the MOS transistor Q2.

A drain of the MOS transistor Q2 is connected to the node N4, and a source thereof is connected to one end of the resistor element R3 via a node N5. The other end of the resistor element R3 is grounded.

In the above-described configuration, the output current detection circuit 20 detects a drain current I_{d} which flows in the MOS transistor Q1. Then, the output current detection circuit 20 generates a voltage VR3 corresponding to the drain current I_{d} by using the resistor element R3, and outputs the voltage VR3 to the overcurrent detection circuit 10.

To be more specific, the amplifier AMP applies a voltage, which corresponds to a potential difference between the node N2 and node N4, to the gate of the transistor Q2. Specifically, the transistor Q2 passes a drain current corresponding to this potential difference. As a result, the potential of the node N2 and the potential of the node N4 become equal. Then, the voltage VR3 occurring in the resistor element R3 is expressed by the following equation (1).

VR3={(r₁×r₃)/r₂}×I_{d} (1)

where r₁, r₂ and r₃ are resistance values of the resistor elements R1, R2 and R3, respectively, and I_{d} is the drain current of the transistor Q1.

As indicated by the equation (1), the voltage VR3 varies in accordance with the value of the drain current I_{d}. Specifically, the drain current I_{d} can be converted to the voltage VR3.

Next, the overcurrent detection circuit 10 will be described. The overcurrent detection circuit 10 includes a constant current source 11, a pnp-type bipolar transistor Q3, a comparator COMP, a constant voltage source 12, a resistor element R4, and a resistor element R5.

The constant current source 11 outputs to a node N7 a constant current I_{c1} which corresponds to a voltage VREG that is supplied to a node N6.

The transistor Q3 has an emitter connected to the node N7, has a base connected to a node N8, and has a collector grounded. The transistor Q3 has a negative temperature characteristic in a base-emitter voltage V_{BEQ3}. Specifically, as an ambient temperature T becomes higher, the value of the voltage V_{BEQ3} becomes smaller. In one example, V_{BEQ3} of the transistor Q3 according to the present embodiment has a temperature characteristic of, e.g. −2 [mV/° C.].

The constant voltage source 12 generates a voltage VREF1. The voltage VREF1 is a value based on a voltage VBGR from a band gap reference circuit (hereinafter “BGR circuit”) which is not shown, and the voltage VREF1 is a constant value in relation to the temperature T.

One end of the resistor element R4 is connected to a node N7, and the other end thereof is connected to a node N8. One end of the resistor element R5 is connected to the node N8, and the other end thereof is grounded.

The resistor element R4 and resistor element R5 are fabricated at the same time, and the resistor element R4 and resistor element R5 have the same size (e.g. have a shape such as a rectangular shape, and are formed of the same element material). Accordingly, if attention is paid to one chip on which the present overcurrent protection circuit 1 is mounted, a variance between elements due to the resistor element R4 and resistor element R5 can be reduced with respect to the voltage (hereinafter “VREF2”) at the node N7.

When the hFE (current amplification factor) of the transistor Q3 is sufficiently high (e.g. 1000), the voltage VREF2 of the node N7 is expressed by the following equation (2).

VREF2≈{(r₄+r₅)/r₄}×V(T)_{BEQ3} (2)

Here, V(T)_{BEQ3} has a negative temperature characteristic in which voltage lowers in accordance with a temperature rise, and varies at, e.g. −2 [mV/° C.]. Accordingly, the voltage VREF2 also has a negative temperature characteristic.

The comparator COMP includes three input terminals, namely two non-inversion input terminals (+) and one inversion input terminal (−), and an output terminal. The voltage VREF1 is input from the constant voltage source 12 to one of the two non-inversion input terminals (+), and the voltage VREF2 at the node N7 is input to the other. In addition, the voltage VR3 is input to the inversion input terminal. Besides, the comparator COMP compares the voltage VR3 and a reference voltage VREF which is based on the voltage VREF1 and/or VREF2, and outputs a voltage, which corresponds to the comparison result, to the controller 30.

Like the above-described configuration, the overcurrent detection circuit 10 generates the voltages VREF1 and VREF2. Then, the overcurrent detection circuit 10 compares the voltage VR3, which the output current detection circuit 20 outputs, with the reference voltage VREF based on the voltage VREF1 and voltage VREF2. When the voltage VR3 is greater than the reference voltage VREF, the drain current I_{d} is determined to be an overcurrent. Then, the comparator COMP outputs a voltage of “L” level as a determination result to the controller 30. On the other hand, when the voltage VR3 is less than the reference voltage VREF, the drain current I_{d} is determined not to be an overcurrent. Then, the comparator COMP outputs a voltage of “H” level to the controller 30.

Next, the controller 30 will be described. When the drain current I_{d} is determined to be an overcurrent, i.e. when the comparator COMP outputs “L” level, the controller 30 turns off the MOS transistor Q1. On the other hand, when the drain current I_{d} is determined not to be an overcurrent, i.e. when the comparator COMP outputs “H” level, the controller 30 turns on the MOS transistor Q1.

1.2 Details of Overcurrent Detection Circuit 10

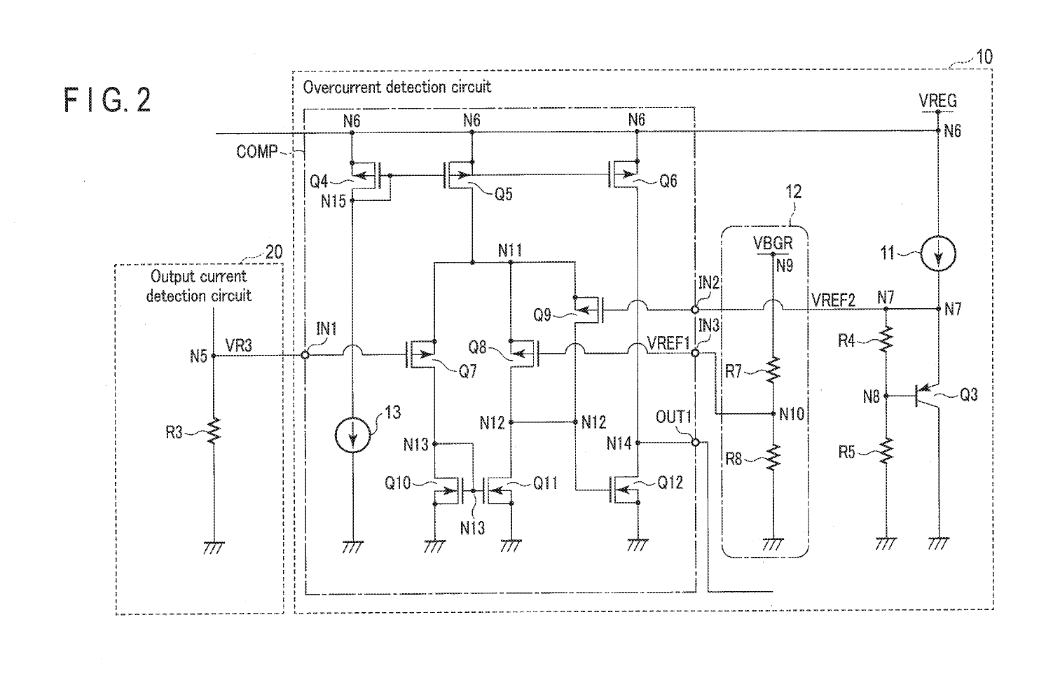

Next, referring to FIG. 2, the details of the overcurrent detection circuit 10 will be described, with particular attention paid to the comparator COMP and constant voltage source 12. In FIG. 2, the circuit structural components described with reference to FIG. 1 are denoted by like reference numerals, and a description thereof is omitted. FIG. 2 is a circuit diagram illustrating the details of the overcurrent detection circuit 10, with attention paid to the comparator COMP and constant voltage source 12.

1.2.1 Re: Constant Voltage Source 12

The constant voltage source 12 includes a resistor element R7 and a resistor element R8.

One end of the resistor element R7 is connected to a node N9 to which a voltage VBGR from a BGR circuit (not shown) is supplied, and the other end thereof is connected to a node N10. In addition, one end of the resistor element R8 is connected to the node N10, and the other end thereof is grounded.

The constant voltage source 12 outputs the voltage VREF1 from the node N10. The voltage VREF1 is expressed by the following equation (3).

VREF1=(r₈/r₇+r₈)×V_{BGR} (3)

Here, r₇ and r₈ are resistance values of the resistor element R7 and resistor element R8.

The resistor element R7 and resistor element R8 are fabricated at the same time, for example, by element patterns of an identical shape, such as a rectangular shape, in the fabrication process of the resistor element R7 and resistor element R8.

1.2.2 Re: Comparator COMP

The comparator COMP includes p-channel MOS transistors Q4 to Q12, n-channel MOS transistors Q10 to Q12, a constant current source 13, input terminals IN1 to IN3, and an output node OUT1.

The sources of the MOS transistors Q4 to Q6 are commonly connected to the node N6, and the voltage VREG is applied to the node N6. In addition, the gates of the MOS transistors Q4 to Q6 are commonly connected to a node N15. Specifically, the transistors Q4 to Q6 constitute a current mirror circuit.

The constant current source 13 causes a constant current I_{c2} to flow through the drain (node N15) of the MOS transistor Q4. Accordingly, the current I_{c2} also flows, as a drain current, through the transistors Q5 and Q6 which constitute, together with the transistor Q4, the current mirror circuit.

The MOS transistor Q7 has a source connected to a node N1, has a drain connected to a node N13, and has a gate connected to the input terminal IN1. The voltage VR3 is supplied to this input terminal IN1. The MOS transistor Q7 functions as the inversion input terminal (−) of the comparator COMP.

The MOS transistor Q8 has a source connected to the node N11, has a drain connected to a node N12, and has a gate connected to the input terminal IN3. The MOS transistor Q8 functions as one of the non-inversion input terminals (+).

Furthermore, the MOS transistor Q9 has a source connected to the node N11, has a drain connected to the node N12, and has a gate connected to the input terminal IN2. The MOS transistor Q9 functions as one of the non-inversion input terminals (+).

The drain and gate of the MOS transistor Q10 are commonly connected to the node N13. In addition, the source of the MOS transistor Q10 is grounded. The MOS transistor Q11 has a drain connected to the node N12, has the other end grounded, and has a gate connected to the node N13. Specifically, the MOS transistor Q10 and MOS transistor Q11 constitute a current mirror circuit.

In addition, the MOS transistor Q12 has a drain connected to a node N14 (output node OUT1), has a source grounded, and has a gate connected to the node N12.

Here, the voltage at the node N14 is output from the output node OUT1 of the comparator COMP. The signal level (“L” level or “H” level) of this output signal is determined according to whether the MOS transistor Q12 is turned on or off. In addition, whether the MOS transistor Q12 is turned on or off depends on the current drive capability of the MOS transistor Q7 to MOS transistor Q9.

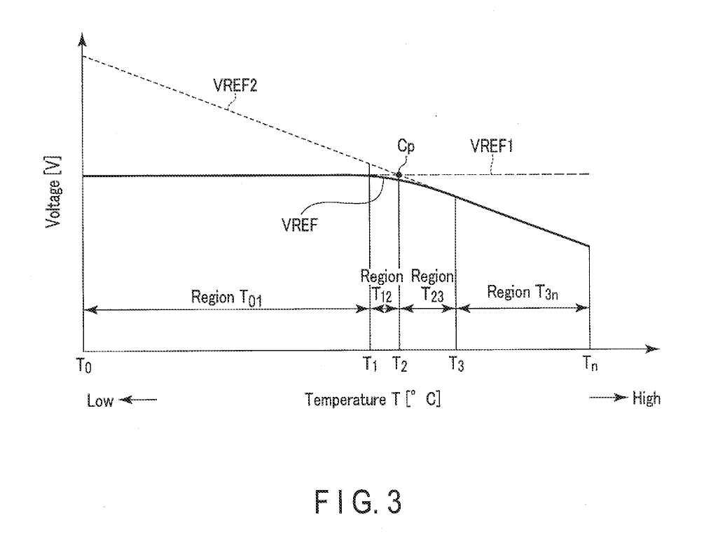

Next, the reference voltage VREF is described with reference to FIG. 3. FIG. 3 is a graph illustrating variations of the voltages VREF1 and VREF2 and the reference voltage VREF relative to a temperature T.

As illustrated in FIG. 3, VREF1<<VREF2 in a region T₀₁ of temperature T₀ to temperature T₁ (T₀<T₁). In this temperature region, the transistor Q9 is substantially set in the OFF state or is completely set in the OFF state. Accordingly, the voltage VREF1 becomes the reference voltage VREF.

In addition, in a region T₁₂ of temperature T₁ to temperature T₂ (T₀<T₁<T₂), VREF1<VREF2. However, in this temperature region, unlike the region T₀₁, not only the transistor Q8 but also the transistor Q9 begins to pass an electric current. Thus, a value based on both the voltage VREF1 and voltage VREF2 becomes the reference potential VREF. However, as regards the influence on the reference voltage VREF in this temperature region T₁₂, VREF1 is dominant over VREF2.

At temperature T₂, VREF1=VREF2. At temperature T₂, the influence of VREF2 on the reference voltage VREF becomes equal to the influence of VREF1 on the reference voltage VREF. In addition, if the chip temperature T reaches a region T₂₃ of temperature T₂ to temperature T₃ (T₀<T₁<T₂, <T₃), VREF1>VREF2. Specifically, in the region T₂₃, like the region T₁₂, VREF is determined based on both VREF1 and VREF2. However, conversely to the case of the region T₁₂, VREF2 becomes dominant over VREF1.

Finally, in a region T₃ₙ of temperature T₃ to temperature Tₙ (T₀<T₁<T₂, <T₃<Tₙ), the transistor Q8 is substantially set in the OFF state or is completely set in the OFF state, and the voltage VREF2 becomes the reference potential VREF.

In the above description, it was described that the voltage VREF1 is substantially constant relative to the chip temperature T, whereas the voltage VREF2 has a negative temperature characteristic. However, for example, both voltages may be defined by voltage variation ratios relative to the chip temperature T. In this case, such a relationship is established that the variation ratio of the voltage VREF1 to the chip temperature T is less than the variation ratio of the voltage VREF2 to this temperature. Specifically, there may be a case in which not only VREF2 but also VREF1 has a temperature characteristic. In addition, there may be a case in which at least one of both voltages has a positive temperature characteristic, and this relationship may be chosen as needed. In the description below, in some cases, the region T₀₁ and region T₁₂ are referred to as “low-temperature to normal-temperature region”, and the region T₁₂ and region T₃ₙ are referred to as “high-temperature region”.

1.3 Re: Operation of Overcurrent Protection Circuit 1

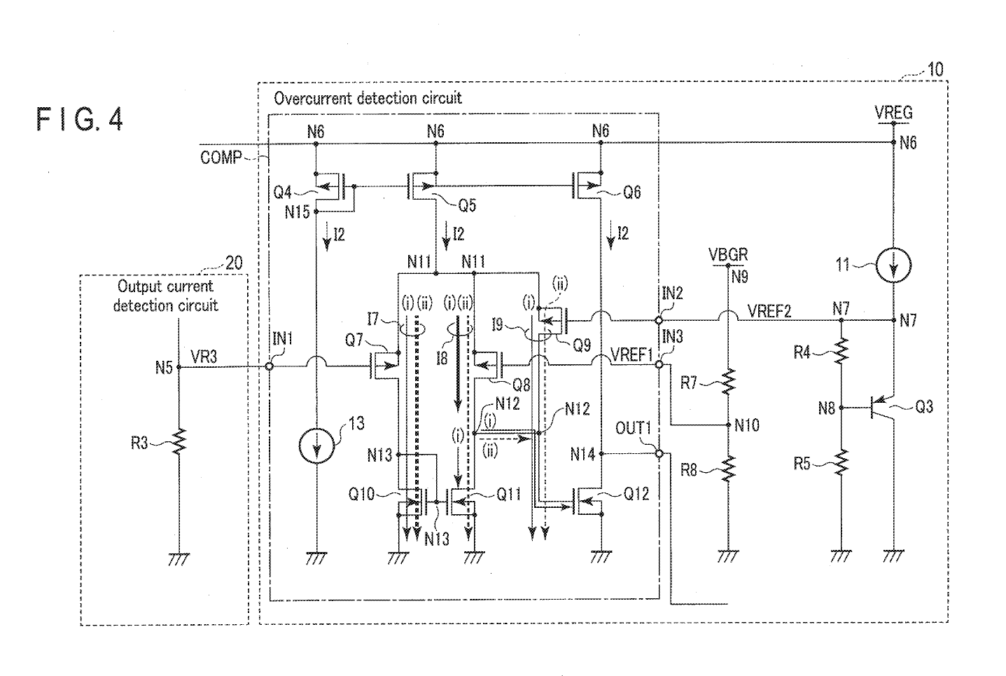

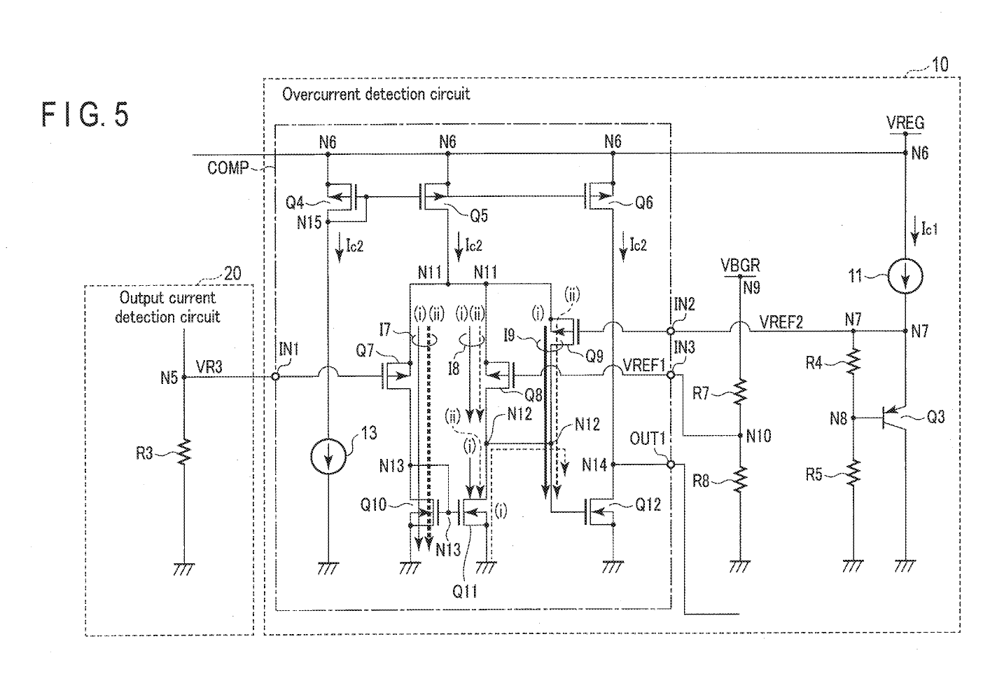

Next, the operation of the overcurrent protection circuit 1 with the above-described configuration will be described with reference to FIG. 4 and FIG. 5, with particular attention being paid to the comparator COMP.

Hereinafter, the case of VR3>VREF is described as (i) Case 1, and the case of VR3≤VREF is described as (ii) Case 2. In addition, FIG. 4 illustrates a comparison operation of the comparator COMP in the region T₀₁ and region T₁₂, and FIG. 5 illustrates a comparison operation of the comparator COMP in the region T₂₃ and region T₃ₙ. Besides, current in Case 1 is indicated by “solid line”, and current in Case 2 is indicated by “dotted line”. Moreover, the amount of current, which each MOS transistor passes, is indicated by a line width, and it is assumed that the amount of current is greater as the line width becomes greater.

1.3.1 Re: Case 1

To begin with, as described above, at the time of the low temperature to normal temperature, VREF2>VREF1 (see the region T₀₁ and region T₁₂ in FIG. 3). Accordingly, a current I₈ (in FIG. 4, (i) thick solid-line arrow), which the MOS transistor Q8 passes, is sufficiently greater than a current I₉ (in FIG. 4, (i) thin solid-line arrow) which the MOS transistor Q9 passes. In addition, in this Case 1, since the relationship of voltage VR3>voltage VREF is established, the current I₈ is greater than a current I₇ (in FIG. 4, (i) thin solid-line arrow) which the MOS transistor Q7 passes.

Accordingly, the potential of the node N13 is increased by the current I₇, and the MOS transistors Q10 and Q11 are turned on. However, since the relationship of current I₇<current I₈ is established as described above, the current drive capability of the MOS transistor Q11 due to the magnitude of the current I₇ is less than the current drive capability of the MOS transistor Q8, and does not have the capability to pass the entirety of the current I₈.

As a result, part of the drain current of the transistor Q8 and the drain current of the transistor Q9 flow into the node N12, and the potential of the node N12 rises. Consequently, since the MOS transistor Q12 is turned on, the potential of the node N14 changes to the ground (“L”) level. In addition, this “L” level signal is output from the output node OUT1 as an output signal of the comparator COMP.

Besides, since the value of the voltage VREF2 becomes lower as the chip temperature T becomes higher, the current drive capability of the MOS transistor Q9 also becomes higher. On the other hand, since the current drive capability of the MOS transistor Q11 due to the magnitude of the current I₇ does not change, a still greater current 19 flows into the node N12. Thus, since a still greater voltage is applied to the MOS transistor Q12, the capability of drawing in the potential of the node N14 by the MOS transistor Q12 becomes greater.

If the chip temperature T further rises and reaches the region T₂₃, the current I₉ (in FIG. 5, (i) thick solid-line arrow), which the MOS transistor Q9 passes, becomes greater than the current I₈ (in FIG. 5, (i) thin solid-line arrow), which the MOS transistor Q8 passes. Then, in the present Case 1, the current drive capability of the MOS transistor Q9 becomes greater than the current drive capability of each of the MOS transistors Q7 and Q8. Specifically, the current I₉ (in FIG. 5, (i) thick solid-line arrow), which the MOS transistor Q9 passes, is greater than the current I₇ (in FIG. 5, (i) thin solid-line arrow), which the MOS transistor Q7 passes, and is greater than the current I₈ (in FIG. 5, (i) thin solid-line arrow), which the MOS transistor Q8 passes.

Accordingly, the potential of the node N13 is increased by the current I₇, and the MOS transistors Q10 and Q11 are turned on. However, as described above, since the relationship of current I₇<current I₉ is established, the current drive capability of the MOS transistor Q11 due to the magnitude of the current I₇ is less than current drive capability of the MOS transistor Q9, and the MOS transistor Q11 is not capable of passing the entirety of not only the current I₈ but also the current I₉.

As a result, part of the drain current of the transistor Q8 and the entirety of the drain current of the transistor Q9 flow into the node N12, and the potential of the node 12 rises. Consequently, since the MOS transistor Q12 is turned on, the potential of the node N14 changes to the ground (“L”) level. In addition, this “L” level signal is output from the output node OUT1 as an output signal of the comparator COMP.

In addition, if the chip temperature T reaches the region T₃ₙ, the value of the voltage VREF2 further lowers (see the region T₃ₙ in FIG. 3), and thus the current drive capability of the MOS transistor Q9 further increases. Then, as described above, since the current drive capability of the MOS transistor Q11 due to the magnitude of the current I₇ does not change, a still greater current I₉ flows into the node N12. Consequently, since a still greater voltage is applied to the MOS transistor Q12, the capability of drawing in the potential of the node N14 by the MOS transistor Q12 becomes still greater.

1.3.2 Re: Case 2

Next, Case 2 will be described.

At the time of the low temperature to normal temperature, VREF2>VREF1 (see the region T₀₁ and region T₁₂ in FIG. 3). Specifically, the current I₈ (in FIG. 4, (ii) thick dotted-line arrow), which the MOS transistor Q8 passes, is greater than the current I₉ (in FIG. 4, (ii) thin dotted-line arrow) which the MOS transistor Q9 passes.

In addition, in the Case 2, since the relationship of voltage VR3≤voltage VREF is established, the current I₇ (in FIG. 4, (ii) very thick dotted-line arrow), which the MOS transistor Q7 passes, is greater than each of the current I₈ and current I₉ (in FIG. 4, (ii) thin dotted-line arrow and thick dotted-line arrow) which the MOS transistors Q8 and Q9 pass.

Here, since the potential of the node N13 is increased by the current I₇, and the MOS transistors Q10 and Q11 are turned on.

As described above, in the present Case 2, since the relationship of current I₇>current I₈ is established, the current drive capability of the MOS transistor Q11 due to the magnitude of the current I₇ is greater than the current drive capability of each of the MOS transistors Q8 and Q9, and the MOS transistor Q11 can pass the entirety of the current I₈ and current I₉. In this manner, as well as the current I₈, the current I₉ from the MOS transistor Q9 flows into this MOS transistor Q11.

Then, since the voltage VREF2 becomes lower as the chip temperature T varies toward the region T₁₂, the current drive capability of the MOS transistor Q9 becomes greater. However, since the current drive capability of the MOS transistor Q7 is still greater, the entirety of the current I₉ flows into the MOS transistor Q11.

As a result, since the MOS transistor Q12 keeps the OFF state, the potential of the node N14 changes to “H” level by the drain current from the MOS transistor Q6. In addition, this “H” level signal is output from the output node OUT1 as an output signal of the comparator COMP.

If the temperature further rises and the chip temperature T rises and reaches the region T₂₃, the voltage VREF2<the voltage VREF1 (see the region T₂₃ in FIG. 3).

However, in the present Case 2, since the relationship of voltage VR3 voltage VREF is established, the current I₇ (in FIG. 5, (ii) very thick dotted-line arrow), which the MOS transistor Q7 passes, is still greater than each of the current I₈ and current I₉ (in FIG. 5, (ii) thin dotted-line arrow and thick dotted-line arrow) which the MOS transistors Q8 and Q9 pass.

In other words, the MOS transistor Q10 and MOS transistor Q11, which are turned on by the current I₇, have the current drive capability which can pass the entirety of the current I₉ as well as current I₈.

Specifically, since the capability of bringing the node N12 to the ground (“L”) level by the MOS transistor Q11 is greater than the current drive capability with which the MOS transistor Q9 supplies the current I₉ to the node N12, the potential of the node N12 does not rise, and the MOS transistor Q12 remains in the OFF state.

Accordingly, the potential of the node N14 is raised to “H” level by the current I_{c2} from the MOS transistor Q6, and this signal is output from the output node OUT1 to the controller 30 as an output signal of the comparator COMP. Then, if the chip temperature T reaches the region T₃ₙ, the value of the voltage VREF2 further lowers (see the region T₃ₙ in FIG. 3), and thus the current drive capability of the MOS transistor Q9 further increases. However, as described above, since the relationship of VR3 a VREF is established, the large/small relationship remains unchanged between the current I₇ (in FIG. 5, (ii) very thick dotted-line arrow), which the MOS transistor Q7 passes, and each of the current I₈ and current I₉ (in FIG. 5, (ii) thin dotted-line arrow and thick dotted-line arrow) which the MOS transistors Q8 and Q9 pass.

Specifically, since the capability of bringing the node N12 to the ground (“L”) level by the MOS transistor Q11 is greater than the current drive capability with which the MOS transistor Q9 supplies the current I₉ to the node N12, the potential of the node N12 does not rise, and the MOS transistor Q12 remains in the OFF state.

In this manner, even if there is a change in the relationship between the voltage VREF1 and voltage VREF2 while the chip temperature T is rising and the value of the chip temperature T is transitioning from the region T₀₁, to region T₁₂, to region T₂₃ and to region T₃ₙ, the comparator COMP in the Case 2 does not determine the drain current I_{d} to be an overcurrent. As a result, the MOS transistor Q1 is turned on, and the drain current I_{d} is increased until the voltage VREF1 has a value close to the voltage VR3.

From the above, when voltage VR3≤voltage VREF1, the comparator COMP determines that the drain current I_{d} is not an overcurrent, and the comparator COMP turns on the MOS transistor Q1, and increases the drain current I_{d} until the voltage VREF1 has a value close to the voltage VR3.

1.4 Advantageous Effects of the First Embodiment

According to the overcurrent protection circuit 1 with the above-described configuration, the operational reliability can be improved regardless of the temperature variation. The advantageous effects will be described hereinafter.

In the overcurrent protection circuit 1 with the above-described configuration, the comparator COMP includes the three input terminals (one inversion input terminal and two non-inversion input terminals). In this configuration, (1) the comparator COMP receives the voltage VR3, which corresponds to the drain current I_{d} flowing in the MOS transistor Q1, by the first input terminal (−) which functions as the inversion input terminal, (2) the comparator COMP receives the voltage VREF1, which is supplied from the BGR circuit (not shown) and has no temperature characteristic, by the second input terminal (+) which functions as the non-inversion input terminal, and (3) the comparator COMP receives the voltage VREF2, which varies (lowers) in accordance with the variation (rise) of the chip temperature T of the chip on which the overcurrent protection circuit 1 is amounted, by the third input terminal (+) which functions as the non-inversion input terminal.

In addition, the overcurrent protection circuit 1 compares the voltage VREF, which is determined based on the temperature T, voltage VREF1 and voltage VREF2, with the voltage VR3. For example, when the chip temperature T is a low temperature to normal temperature in the region T₀₁ and region T₁₂, the reference potential VREF is more strongly affected by the voltage VREF1 between the voltage VREF1 and voltage VREF2. On the other hand, when the chip temperature T is a high temperature, the reference potential VREF is more strongly affected by the voltage VREF2 between the voltage VREF1 and voltage VREF2.

In addition, since the reference potential VREF at high temperatures has the negative temperature characteristic, the voltage value thereof can be made lower than at the time of low temperatures (see FIG. 3). Specifically, the drain current I_{d}, which is caused to flow in the MOS transistor Q1, can be more suppressed than at the time of the low temperatures to normal temperature. Thus, even when the chip temperature T is a high temperature, the operation can be stabilized without passing an overcurrent in the MOS transistor Q1.

Moreover, in this configuration, while the overcurrent is suppressed at the time of high temperatures, a sufficient current output can be exhibited even at the time of low temperatures. Specifically, for example, when the reference voltage is determined with reference to the time of high temperatures, i.e. when the reference voltage is set at a relatively low value, it is possible that even if an overcurrent at the time of high temperatures can be suppressed, the current output at the time of low temperatures is limited more than necessary. As regards this point, according to the present embodiment, by using a relatively high reference voltage at the time of low temperatures, a sufficient current output is secured. In other words, it is possible to avoid limiting the current output more than necessary. On the other hand, at the time of high temperatures, a relatively low reference voltage is used. Thereby, the overcurrent can be suppressed as described above. In this manner, both the exhibition of sufficient current supply capability and the suppression of overcurrent can consistently be achieved.

In addition, according to the overcurrent protection circuit 1 with the above-described configuration, the voltage VREF2 is generated as the reference voltage at the time of high temperatures of the chip temperature T, by using the resistor element R4, resistor element R5 and transistor Q3 having the “negative temperature characteristic”. According to this, the voltage VREF2 having the “negative temperature characteristic” can be generated by the configuration in which simple circuits, such as the resistor element R4, resistor element R5 and transistor Q3, are combined. Thus, the circuit configuration does not become complex, and the number of circuit components, which are adopted, is small. Therefore, the circuit area can be reduced.

Furthermore, according to the overcurrent protection circuit 1 with the above-described configuration, the resistor element R4 and resistor element R5 are fabricated at the same time, for example, by element patterns of an identical shape such as a rectangular shape in the fabrication process of the resistor element R4 and resistor element R5. According to this, the influence on the voltage VREF2 due to a variance among the elements can be suppressed.

### 2. Second Embodiment

Next, a semiconductor integrated circuit according to a second embodiment will be described. In the second embodiment, the overcurrent protection circuit 1 according to the first embodiment is configured such that the voltage level of each of the voltage VREF1 and voltage VREF2 in the overcurrent detection circuit 10 can be switched between a high level and a low level, and a reference voltage switching unit 50, which switches the voltage level between the high level and low level, is further adopted.

2.1 Re: Configuration of Overcurrent Detection Circuit

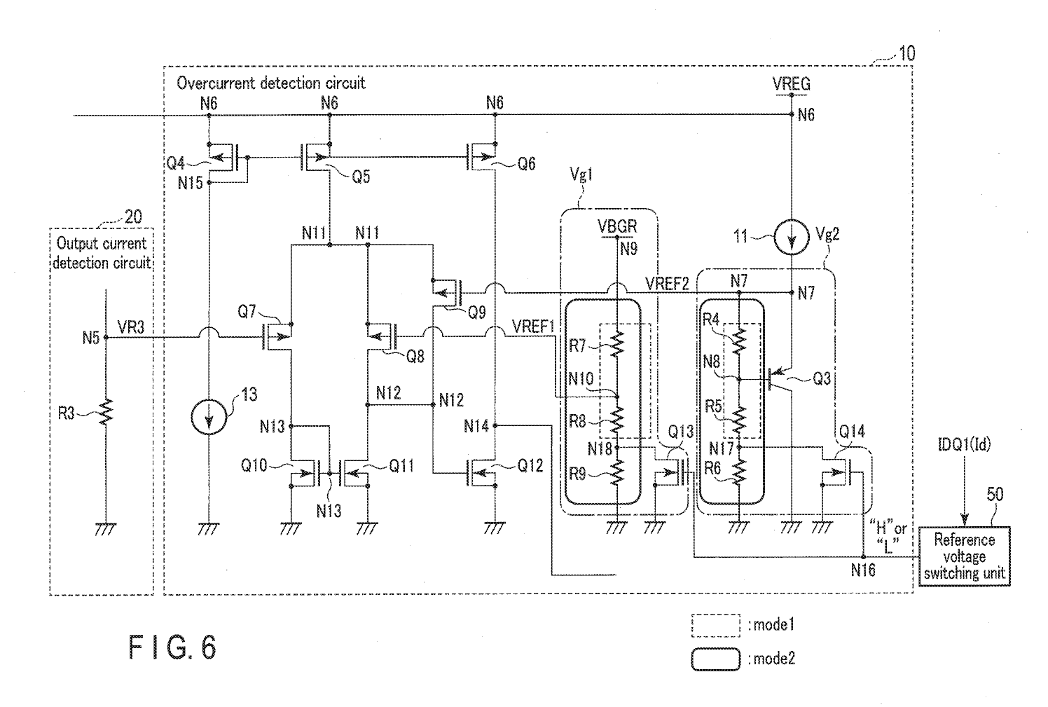

Referring to FIG. 6, a description is given of the configuration of an overcurrent detection circuit 10 in an overcurrent protection circuit 1 according to the second embodiment. In the description below, the same structural parts as in the first embodiment are denoted by like reference numerals, and attention is paid to different structural parts.

The overcurrent detection circuit 10 according to the second embodiment further includes a resistor element R6 and a resistor element R9, as well as a MOS transistor Q13 and a MOS transistor Q14. Thereby, a first voltage generator Vg1 and a second voltage generator Vg2, which will be described below, are constituted.

2.1.1 Re: Circuit Configuration of First Voltage Generator Vg1

The first voltage generator Vg1 is configured by combining the newly provided resistor element 9 and MOS transistor Q13 with the originally provided resistor element R7 and resistor element R8.

One end of the resistor element R9 is connected to a node N18, and the other end thereof is grounded. In addition, the MOS transistor Q13 has a drain connected to the node N18, has a source grounded, and has a gate connected to a node N16.

This first voltage generator Vg1 has a function of generating voltages VREF1 with different voltage levels.

Specifically, when the MOS transistor Q13 is ON, the first voltage generator Vg1 generates a voltage VREF1 (hereinafter [mode 1]) of the above-described equation (1) corresponding to the resistor element R7 and resistor element R8 which are surrounded by a broken line. On the other hand, when the MOS transistor Q13 is OFF, the first voltage generator Vg1 generates a voltage VREF1 (hereinafter [mode 2]) corresponding to the resistor element R7, resistor element R8 and resistor element R9 which are surrounded by a solid line.

Here, the voltage VREF1 in [mode 2] is expressed by the following equation (4).

VREF1={(r₈+r₉)/(r₇+r₈+r₉)}×V_{BGR} (4)

Here, r₉ is the resistance value of the resistor element R9.

2.1.2 Re: Circuit Configuration of Second Voltage Generator Vg2

The second voltage generator Vg2 is configured by combining the newly provided resistor element R6 and MOS transistor Q14 with the originally provided resistor element R4 and resistor element R5.

One end of the resistor element R6 is connected to a node N17, and the other end thereof is grounded. In addition, the MOS transistor Q14 has a drain connected to the node N17, has a source grounded, and has a gate connected to the node N16.

Like the first voltage generator Vg1, the second voltage generator Vg2 with the above-described configuration has a function of generating voltages VREF2 with different voltage levels.

Specifically, when the MOS transistor Q14 is ON, the second voltage generator Vg2 generates a voltage VREF2 (hereinafter [mode 1]) corresponding to the resistor element R4 and resistor element R5 which are surrounded by a broken line. On the other hand, when the MOS transistor Q14 is OFF, the second voltage generator Vg2 generates a voltage VREF2 (hereinafter [mode 2]) which is expressed by the following equation (5) and corresponds to the resistor element R4, resistor element R5 and resistor element R6 which are surrounded by a solid line.

Here, the voltage VREF2 in [mode 2] is expressed by the following equation (5).

VREF2={(r₄+r₅+r₆)/r₄}×V(T)_{BEQ3} (5)

Here, r₆ is the resistance value of the resistor element R6.

2.2 Re: Reference Voltage Switching Unit 50

The reference voltage switching unit 50 has a function of supplying a signal of “L” level or “H” level to the node N16.

While the reference voltage switching unit 50 is supplying the signal of “H” level, the reference voltage switching unit 50 functions as an overcurrent detection mode.

The overcurrent detection mode is a function of turning off the MOS transistor Q1 and detecting the stop of the drain current I_{d}, as a result of the overcurrent detection circuit 10 determining that the drain current I_{d} is an overcurrent.

On the other hand, while the reference voltage switching unit 50 is supplying the signal of “L” level, the reference voltage switching unit 50 functions as a restoration mode.

The restoration mode is a function in which the MOS transistor Q1 is turned on once again by the driver 40, based on the control from the controller 30, and the drain current I_{d}, which has begun to flow to the external load RL, is detected. This function is executed regardless of the chip temperature T (high, low).

Here, the voltage level of the voltage VREF, which is the reference voltage of the voltage VR3 corresponding to the drain current I_{d}, varies in accordance with the chip temperature T. In the other respects, the operation of the overcurrent protection circuit 1 is the same as in the first embodiment, and a description of the operation of the entirety of the overcurrent protection circuit 1 is omitted here.

Hereafter, the switching operation of the voltage level by the overcurrent detection circuit 10 and reference voltage switching unit 50 will be described.

2.3 Re: Operation of Overcurrent Detection Circuit 10 and Reference Voltage Switching Unit 50

To begin with, while the drain current I_{d} is flowing, the reference voltage switching unit 50 functions as the overcurrent detection mode. Specifically, the reference voltage switching unit 50 outputs the voltage of “H” level to the node N16.

In this case, the MOS transistors Q13 and Q14 are turned on.

Thus, the first voltage generator Vg1 supplies, as the voltage VREF1, a value (the value corresponding to the equation (3) described in the first embodiment), which corresponds to the resistance value r₇ of the resistance element R7 and the resistance value r₈ of the resistance element R8, to the MOS transistor Q8 (see the broken line in FIG. 6).

The same applies to the voltage VREF2.

Specifically, the second voltage generator Vg2 supplies, as the voltage VREF2, a value (the value corresponding to the equation (2) described in the first embodiment), which corresponds to the resistance value r₄ of the resistance element R4 and the resistance value r₅ of the resistance element R5, to the MOS transistor Q9 (see the broken line in FIG. 6).

Accordingly, the comparator COMP outputs a result (an overcurrent or not) which is obtained by comparing the voltage VREF (see FIG. 3), which is the voltage corresponding to the overcurrent detection mode and varies depending on the temperature T, with the voltage VR3.

For example, when the comparator COMP determines that the drain current I_{d} is an overcurrent, the comparator COMP outputs a signal of “L” level to the controller 30. The driver 40 turns off the transistor Q1 by the control signal from the controller 30 which received this signal level. In short, the driver 40 stops the drain current I_{d}.

Thereafter, if the reference voltage switching unit 50 detects that the drain current I_{d}, which was temporarily stopped, has begun to flow once again, the reference voltage switching unit 50 switches the overcurrent detection mode, which is set thus far, to the restoration mode, and raises the voltage levels of the voltage VREF1 and voltage VREF2. At this time, the reference voltage switching unit 50 outputs the voltage of “L” level to the node N16.

Specifically, the first voltage generator Vg1 supplies, as the voltage VREF1, the value of the above equation (4) to the MOS transistor Q8 (see the solid line in FIG. 6).

Similarly, the second voltage generator Vg2 supplies, as the voltage VREF2, the value of the above equation (5) to the MOS transistor Q9 (see the solid line in FIG. 6).

The comparator COMP outputs a result (an overcurrent or not) which is obtained by comparing the voltage VREF (see FIG. 3), which is the voltage corresponding to the restoration mode and varies depending on the temperature T, with the voltage VR3.

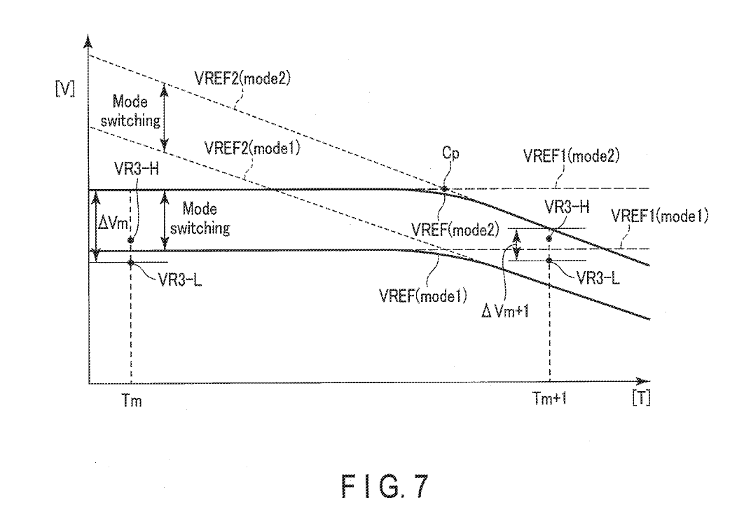

Hereinafter, referring to FIG. 7, a description will be given of the switching operation by the reference voltage switching unit 50 of the voltage levels of the voltage VREF1 which the first voltage generator Vg1 generates, and the voltage VREF2 which the second voltage generator Vg2 generates.

FIG. 7 is a conceptual view illustrating the switching of the voltage levels of the voltage VREF1 and voltage VREF2 from [mode 1] to [mode 2].

Here, the switching operations of the voltage VREF1 and voltage VREF2 are described with respect to a temperature Tₘ (low temperature to normal temperature) and a temperature Tₘ₊₁ (high temperature), separately. In this case, it is assumed that the voltage VR3 at the node N3 is a voltage VR3-H (a voltage before turn-off of the MOS transistor Q1) and a voltage VR3-L (a voltage after the MOS transistor Q1 is turned on once again).

2.3.1 Case of Temperature Tₘ (Low Temperature to Normal Temperature)

To begin with, a case is considered in which the relationship of voltage VR3-H>voltage VREF is established (the drain current I_{d} is an overcurrent).

In this case, as in the above-described operation, the MOS transistor Q1 is turned off by the controller 30, which received the signal from the comparator COMP, and the driver 40.

It is assumed that, thereafter, the MOS transistor Q1 is turned on once again by the controller 30, which further received the signal from the comparator COMP, and the driver 40. Then, the reference voltage switching unit 50, which detects that the drain current I_{d} has begun to flow, switches the overcurrent detection mode, which is set thus far, to the restoration mode.

Specifically, the reference voltage switching unit 50 switches [mode 1] to [mode 2] and raises the voltage VREF1 and voltage VREF2. Thereby, for example, a potential difference between VREF1 and voltage VR3-L at temperature Tₘ is set at ΔVₘ (see an arrow direction in FIG. 7).

Here, it is assumed that the voltage VR3 at a time when the MOS transistor Q1 is turned on once gain is near the voltage level in [mode 1] (in FIG. 7, voltage VR3-L, voltage VR3-H).

On the other hand, since the voltage VREF1 and voltage VREF2 reach the voltage levels of [mode 2], the voltage VR3 is determined to be a small value. Specifically, it is determined that the drain current I_{d} is not an overcurrent.

Accordingly, the comparator COMP outputs the signal of “L” level to the controller 30, thereby to keep the MOS transistor Q1 in the ON state.

2.3.2 Case of Temperature Tₘ₊₁ (High Temperature)

A case is considered in which, like the above, the relationship of voltage VR3-H>voltage VREF is established, and, as a result, the comparator COMP determined that an overcurrent is flowing in the MOS transistor Q1.

In this case, too, the reference voltage switching unit 50 executes similar detection. Specifically, the MOS transistor Q1 is turned on/off by the controller 30, which received the signal from the comparator COMP, and the driver 40, and the reference voltage switching unit 50 detects the drain current I_{d} at each time.

Based on the detection, like the above, the overcurrent detection mode is switched to the restoration mode.

Specifically, the reference voltage switching unit 50 switches [mode 1] to [mode 2] and raises the voltage VREF1 and voltage VREF2. Thereby, for example, a potential difference between VREF2 and voltage VR3-L at temperature Tₘ₊₁ is set at ΔVₘ₊₁ (see an arrow direction in FIG. 7).

2.4 Advantageous Effects According to the Second Embodiment

Also with the overcurrent protection circuit 1 having the above-described configuration, the operational reliability can be improved regardless of the temperature variation. The advantageous effects will be described hereinafter.

In the overcurrent protection circuit 1 with the above-described configuration, the first voltage generator Vg1 and second voltage generator Vg2, which constitute the overcurrent detection circuit 10, are configured to switch the voltage levels of the voltage VREF1 and voltage VREF2 between the high level and low level, and the resistor element R6 and resistor element R9, as well as the MOS transistor Q13 and MOS transistor Q14, are newly provided.

In addition, the reference voltage switching unit 50 is further provided which can switch the voltage levels between the high level and low level, such that the voltage levels are raised in the overcurrent mode ([mode 1]) and the voltage levels are lowered in the restoration mode ([mode 2]).

According to this, when the MOS transistor Q1 is turned on once again, even if the voltage level of the voltage VR3 is the voltage VR3-L at the temperature Tₘ and temperature Tₘ+1, the voltage levels of the voltage VREF1 and voltage VREF2 are raised to the voltages corresponding to [mode 2] by the reference voltage switching unit 50 which detects the drain current I_{d} that has begun to flow once again.

Thus, an allowance of ΔVₘ can be provided to the voltage VR3-L relative to the VREF1 ([mode 2]) at the temperature Tₘ, and an allowance of ΔVₘ₊₁ can be provided to the voltage VR3-L relative to the VREF2 ([mode 2]) at the temperature Tₘ₊₁.

The reason why this configuration is adopted is that, for example, when the MOS transistor Q1 is restored and turned on once again after the overcurrent was determined, the voltage VR3 corresponding to the drain current I_{d} is in the neighborhood of the voltage VREF1. Then, it is considered that there arises such a problem that the MOS transistor Q1 is repeatedly turned on and off.

However, in the overcurrent protection circuit 1 according to the second embodiment, as described above, the allowances of ΔVₘ and ΔVₘ₊₁ can be provided to the voltage VR3-L at all temperatures T from the low temperature to high temperature. Therefore, the above situation can be prevented.

Note that “the neighborhood of the voltage VREF1” includes both a value of the voltage VR3 which is greater than the voltage VREF1, and a value of the voltage VR3 which is less than the voltage VREF1, and means a voltage at which the MOS transistor Q1 is repeatedly turned on or off.

### 3. Third Embodiment

Next, the configuration of a semiconductor integrated circuit according to a third embodiment will be described. In the third embodiment, the constant voltage source BGR circuit (not shown), which generates the voltage VREF1 in the overcurrent detection circuit 10 according to the first embodiment, is omitted, and, instead, a constant current source 14 is adopted.

Note that this embodiment, too, adopts the configuration in which the voltage level switching mode is executed by the reference voltage switching unit 50.

3.1 Re: Circuit Configuration of First Voltage Generator Vg1

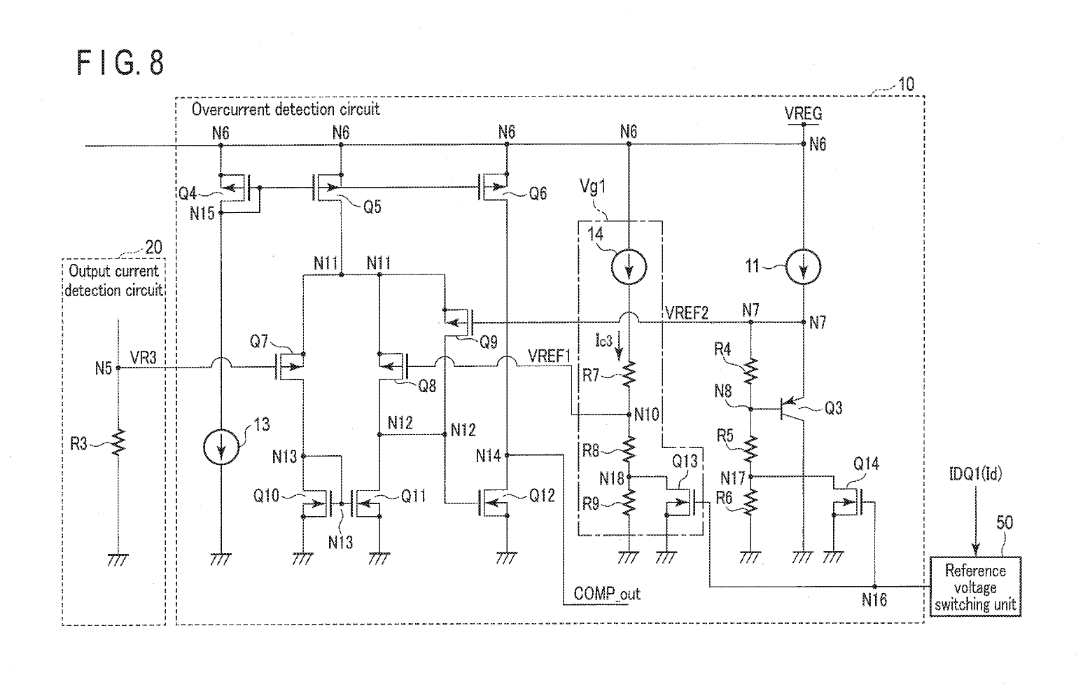

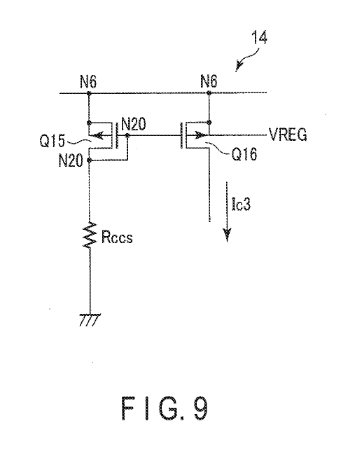

Referring to FIG. 8 and FIG. 9, a description is given of the configuration of an overcurrent detection circuit 10 according to the third embodiment. In the description below, the same structural parts as in the first embodiment and second embodiment are denoted by like reference numerals, and attention is paid to different structural parts.

FIG. 8 is a circuit diagram in which attention is paid to the overcurrent detection circuit 10 (first voltage generator Vg1) according to the third embodiment.

As illustrated in FIG. 8, the constant current source 14 in the first voltage generator Vg1 supplies a constant current I_{c3} to the resistor element R7.

Next, a detailed circuit configuration of the constant current source 14 is illustrated with reference to FIG. 9.

FIG. 9 is a view illustrating the detailed circuit configuration of the constant current source 14.

The constant current source 14 includes a MOS transistor Q15, a MOS transistor Q16, and a resistor element Rccs.

The MOS transistor Q15 has a source connected to the node N6, and has a drain and a gate commonly connected at a node N20.

In addition, the MOS transistor Q16 has a source connected to the node N6, has a drain connected to the one end of the resistor element R7 illustrated in FIG. 8, and has a gate connected to the node N20. Specifically, the MOS transistor Q15 and MOS transistor Q16 constitute a mirror circuit.

In the first voltage generator Vg1 with the above-described configuration, the constant current source 14 has a function of outputting the constant current I_{c3} to the resistor elements R7, R8 and R9, based on the voltage VREG which is supplied to the node N6.

Here, for example, if the reference voltage switching unit 50 outputs the voltage of “H” level to the node N16 in order to function as [mode 1], the other end of the resistor element R8 is grounded. Thereby, the potential (voltage VREF1) of the node N10 is expressed by the following equation (6).

VREF1=R7×I_{c3} (6)

On the other hand, if the reference voltage switching unit 50 outputs the voltage of “L” level to the node N16 in order to function as [mode 2], the potential (voltage VREF1) of the node N10 is expressed by the following equation (7).

VREF1=(R7+R8)×I_{c3} (7)

3.2 Advantageous Effects According to the Third Embodiment

According to the overcurrent protection circuit 1 with the above-described configuration, the MOS transistor Q16 constitutes, together with the MOS transistor Q15, the mirror circuit.

Accordingly, the MOS transistor Q16 passes, to the resistor element R7 (see FIG. 8), the same current as the constant current I_{c3} which is passed from the MOS transistor Q15 to the resistor element Rccs.

In addition, the resistor element Rccs is fabricated, for example, at the same time and with the same shape, such as a rectangular shape, in the fabrication process of the resistor element R7 and resistor element R8.

Thus, even when the value of the resistor element Rccs varied due to the variation of the chip temperature T, the same variation occurs in the resistor element R7 and resistor element R8. Thus, the constant voltage VREF1 can be generated without depending on the temperature T.

In addition, according to the overcurrent protection circuit 1 with the above-described configuration, a desired resistance value is set, for example, by one, or a combination, of element patters of the same shape such as a rectangular shape.

Specifically, the voltage variation ratios from [mode 1] to [mode 2] in the voltage VREF1 and voltage VREF2 can easily be matched by matching the ratios of element patterns of the resistor elements R4, R5 and R6 and the resistor elements R7 and R8.

Moreover, according to the overcurrent protection circuit 1 with the above-described configuration, the constant voltage source BGR circuit (not shown) is omitted, and, instead, the constant current source 14 is adopted.

According to this, the voltage value of the voltage VREF1 can be made greater.

The reason for this is that the constant voltage source BGR circuit (not shown) generally sets its output voltage at about 1.2 [V], and thus the voltage VREF1 is limited to a value obtained by dividing 1.2 [V].

However, the constant current source 14 can set the voltage VREF1 by the values of the resistor element Rccs, resistor element R7 and resistor element R8. Thus, the degree of freedom can be given to the value of the voltage VREF1.

Note that the MOS transistor Q4 to MOS transistor Q12, which constitute the comparator COMP in the first embodiment to the third embodiment, may be composed of bipolar transistors BIPTr.

In this case, the MOS transistor Q4 to MOS transistor Q9 are transistors each having an emitter terminal (p type), a base terminal (n type) and a collector terminal (p type), and the MOS transistor Q10 to MOS transistor Q12 are transistors each having an emitter terminal (n type), a base terminal (p type) and a collector terminal (n type).

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor integrated circuit comprising:
a comparator including a first input terminal configured to receive a first voltage, a second input terminal configured to receive a second voltage having a negative temperature characteristic, and a third input terminal configured to receive a third voltage corresponding to a current flowing in a switching element, the comparator being configured to compare a reference voltage, which is based on at least one of the first voltage and the second voltage, with the third voltage; and
a first controller configured to control the switching element in accordance with a comparison result of the comparator,
wherein the second voltage is greater than the first voltage at a first temperature and is less than the first voltage at a second temperature which is higher than the first temperature,
the comparator is configured to compare the first voltage and the third voltage at the first temperature, and
the comparator is configured to compare the second voltage and the third voltage at the second temperature.

2. The semiconductor integrated circuit of claim 1, wherein a variation ratio of the first voltage to a temperature is less than a variation ratio of the second voltage to the temperature,
the first controller is configured to turn off the switching element in a first temperature region including the first temperature, when the comparator determines that the third voltage is greater than the first voltage, and
the first controller is configured to turn off the switching element in a second temperature region which is higher than the first temperature region and includes the second temperature, when the comparator determines that the third voltage is greater than the second voltage.

3. The semiconductor integrated circuit of claim 2, wherein the comparator is configured to compare a voltage based on both the first voltage and the second voltage, with the third voltage, in a third temperature region between the first temperature region and the second temperature region.

4. The semiconductor integrated circuit of claim 2, wherein the first voltage is substantially constant relative to the temperature.

5. The semiconductor integrated circuit of claim 1, further comprising a transistor with a base-emitter voltage having a negative temperature characteristic,
wherein the negative temperature characteristic is imparted to the second voltage by utilizing the base-emitter voltage.

6. The semiconductor integrated circuit of claim 1, wherein the semiconductor integrated circuit includes a first mode in which it is detected whether an overcurrent is flowing in the switching element, and a second mode in which the switching element is restored from an OFF state to an ON state once again after it is detected that the overcurrent is flowing in the switching element, and
the semiconductor integrated circuit further comprises a second controller configured to make values of the first voltage and the second voltage in the second mode greater than values of the first voltage and the second voltage in the first mode.

7. The semiconductor integrated circuit of claim 6, wherein temperature characteristics of the first voltage and the second voltage in the second mode are temperature characteristics which are obtained by parallel-shifting to a high voltage side temperature characteristics of the first voltage and the second voltage in the first mode.

8. The semiconductor integrated circuit of claim 7, further comprising:
a first resistor element group including a first resistor element, a second resistor element and a third resistor element which are connected in series, the first resistor element group being configured to generate the first voltage by using a resistor element selected from among the first resistor element, the second resistor element and the third resistor element;
a first transistor connected in parallel with the third resistor element;
a second resistor element group including a fourth resistor element, a fifth resistor element and a sixth resistor element which are connected in series, the second resistor element group being configured to generate the second voltage by using a resistor element selected from among the fourth resistor element, the fifth resistor element and the sixth resistor element; and
a second transistor connected in parallel with the sixth resistor element,
wherein the second controller is configured to turn on, in the first mode, the first transistor and the second transistor, and thereby the first voltage is generated by voltage division in the first resistor element and the second resistor element and the second voltage is generated by voltage division in the fourth resistor element and the fifth resistor element, and
the second controller is configured to turn off, in the second mode, the first transistor and the second transistor, and thereby the first voltage is generated by voltage division in the first resistor element, the second resistor element and the third resistor element and the second voltage is generated by voltage division in the fourth resistor element, the fifth resistor element and the sixth resistor element.

9. The semiconductor integrated circuit of claim 1, further comprising an overcurrent detection circuit and an output current detection circuit,
wherein the overcurrent detection circuit includes:
a constant voltage source including one end which is connected to the first input terminal, and the other end which is grounded;
a first resistor element including one end which is connected to the second input terminal;
a second resistor element including one end which is connected to the other end of the first resistor element, and the other end which is grounded;
a transistor including a first terminal which is connected to the second input terminal, a second terminal which is grounded, and a base which is connected to the first resistor element and the second resistor element; and
a constant current source connected to the second input terminal, and
the output current detection circuit is connected to the third input terminal and connected to the switching element, and detects a current flowing in the switching element.

10. A comparator comprising a first input terminal configured to receive a first voltage, a second input terminal configured to receive a second voltage having a negative temperature characteristic, and a third input terminal configured to receive a third voltage corresponding to a current flowing in a switching element,
wherein the comparator is configured to compare a reference voltage, which is based on at least one of the first voltage and the second voltage, with the third voltage, and configured to output a signal, which controls the switching element, in accordance with a result of the comparison,
the second voltage is greater than the first voltage at a first temperature and is less than the first voltage at a second temperature which is higher than the first temperature,
the comparator is configured to compare the reference voltage, which is based on the first voltage, with the third voltage at the first temperature, and
the comparator is configured to compare the reference voltage, which is based on the second voltage, with the third voltage at the second temperature.

11. The comparator of claim 10, wherein the comparator is configured to compare the reference voltage, which is based on the first voltage and the second voltage, with the third voltage at a third temperature between the first temperature and the second temperature.

12. A comparator configured to receive a first voltage, a second voltage having a negative temperature characteristic, and a third voltage corresponding to a current flowing in a switching element,
wherein the second voltage is greater than the first voltage at a first temperature and is less than the first voltage at a second temperature which is higher than the first temperature,
the comparator is configured to compare the first voltage with the third voltage at the first temperature, and
the comparator is configured to compare the second voltage with the third voltage at the second temperature.

13. The comparator of claim 12, wherein the comparator is configured to compare the reference voltage, which is based on the first voltage and the second voltage, with the third voltage at a third temperature between the first temperature and the second temperature.
